(19) United States
(12) Patent Application Publication
(10) Pub. No.: US 2007/0217171 A1
(43) Pub. Date: Sep. 20, 2007

(54) Modular memory device with connector housed controller

(75) Inventor: Trung V. Le, White Bear Township, MN (US)

Correspondence Address: Attention: Eric D. Levinson;Imation Corp., Legal Affairs, P.O. Box 64898, St. Paul, MN, 55164-0898, US

(73) Assignee: Imation Corp.

(21) Appl. No.: 11/376,830

(22) Filed: Mar. 15, 2006

(51) Int. Cl. H05K 5/00

(52) U.S. Cl. 361/752

(57) ABSTRACT

This disclosure is directed to a compact storage device, such as a flash memory device. The connector of the memory device contains the controller that controls data transfer and storage within a flash memory module (FMM) of the memory device. Preferably, the controller resides completely within the connector to enable the smallest form factor of the flash memory device and the most space for one or more flash memory modules. In this manner, the memory device may store a large quantity of data while being of a small size. Additionally, the connector may also be used with other data transfer or storage devices while the FMM may separately store data within other storage or computing devices.

### TECHNICAL FIELD

The invention relates to compact data storage devices and, more particularly, flash memory devices.

### BACKGROUND

A wide variety of data storage media exist for transferring data from one device to another device. The data storage media may allow users to easily transport data between various devices, computers, and locations. Compact data storage media are particularly desirable for individual users, and are commonly used for the storage and transport of information. A compact data storage medium includes one or more storage elements that store the information within the medium. A connector may be formed on the data storage medium to allow electrical access to the storage elements within the data storage medium so that information can be stored in the storage elements or accessed from the storage elements via electrical signals. The connector typically extends from the data storage medium and any other circuitry used for data transfer or storage.

One of the most popular types of storage elements used in compact data storage media is a flash memory drive. A flash memory drive includes an internal, high-speed solid-state memory capable of persistently storing data without the application of power. A flash memory drive is compact, easy to use, and has no moving parts. Many other types of storage elements may also be used in compact data storage devices, such as electrically-erasable-programmable-read-only-memory (EEPROM), non-volatile random-access-memory (NVRAM), magnetoresistive random access memory (MRAM) and other non-volatile or volatile memory types, such as synchronous dynamic random-access-memory (SDRAM), with battery backup.

Some compact data storage media include a specialized connector for coupling directly to a host computer. For example, a host connector may allow the data storage medium to be coupled directly to a host computer interface of a host computer, such as a Universal Serial Bus (USB) interface, in order to allow data transfer between the storage devices of the host computer and the storage elements of the data storage medium. The use of host connectors on compact data storage media can eliminate the need for specialized readers or specialized media drives designed solely for the data storage media.

Examples of host connectors that may be used for compact data storage media include a personal computer memory card international association (PCMCIA) connector including a 16 bit standard PC Card interface and a 32 bit standard CardBus interface, a Universal Serial Bus (USB) connector, a Universal Serial Bus 2 (USB2) connector, an IEEE 1394 FireWire connector, a Small Computer System Interface (SCSI) connector, an Advance Technology Attachment (ATA) connector, a serial ATA connector, an Integrated Device Electronic (IDE) connector, an Enhanced Integrated Device Electronic (EIDE) connector, a Peripheral Component Interconnect (PCI) connector, a PCI Express connector and a conventional serial or parallel interface connector.

### SUMMARY

In general, the disclosure is directed to a compact storage device, such as a flash memory device. The memory device is portable, which allows a user to transfer data between computing devices and store data in a very small package. The connector of the memory device contains the controller which manages data transfer and storage within a flash memory module (FMM) of the memory device, but memories other than flash memory may also be used. The controller resides completely within the connector to enable the smallest form factor of the memory device and free space for one or more flash memory modules to store a greater capacity of data. In this manner, the memory device may store a large quantity of data while being of a small size.

In some other embodiments, the connector may be an individual component, such that it is used with other data transfer or storage devices, such as IEEE 1394, PCI, or SATA configurations. The connector may also be removable from the memory device to allow for easy memory upgrades. In addition, the connector may be an intelligent connector that allows other digital devices be constructed without controllers, thus reducing the size of the other digital devices.

In other alternative embodiments described herein, the FMM may be used to store data within storage or computing devices other than the memory device. For example, the FMM may be installed in motherboards, digital music players, digital camera, hard drives, video game systems, or other computing devices which use memory.

In one embodiment, the disclosure provides a device for storing data including a device housing, a memory module within the device housing that stores data, and a connector that extends from the device housing. The connector further includes a plurality of electrical contacts that facilitate a connection to a host port and a controller circuit that manages data transfer and data storage. The controller resides outside of the device housing.

In another embodiment, the invention provides a removable connector for a first device including a plurality of electrical contacts that facilitate a connection of the first device to a port of a second device and a controller circuit that manages data transfer between the second device and the first device when the first device and the second device are connected via the removable connector, wherein the removable connector is removable from the first device.

In an additional embodiment, the invention provides a memory module for storing data. The memory module comprises a circuit board, a plurality of electrical contacts that facilitate a connection to a host device, and a memory circuit coupled to the circuit board, wherein the memory circuit includes protection circuitry to protect the memory circuit from a power surge upon insertion of the memory module into the host device while the host device is operating.

The invention may provide one or more advantages. By incorporating a memory controller into the connector element of a device, the memory device may be constructed to be smaller in size relative to a memory device that houses the memory controller outside of the connector. Alternatively, the memory device may increase the data storage capacity by utilizing the space normally used to house the memory controller. A connector that includes a controller may be used with a variety of applications because its compatibility may be flexible to several memory formats. In addition, a separate removable memory module may reduce manufacturing costs and allow a user to easily repair or upgrade the memory of the memory device.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a perspective view of an exemplary flash memory device and computing device.

FIG. 2 is a cross sectional views illustrating various controller locations within exemplary flash memory devices.

FIG. 3 is a top view of an exemplary flash memory device.

FIG. 4 is a top view of an exemplary flash memory module (FMM).

FIG. 5 is a block diagram of components of an exemplary flash memory device.

FIG. 6 is a flow diagram illustrating an exemplary life cycle of a flash memory device with a removable flash memory module.

### DETAILED DESCRIPTION

The description herein is directed to a memory device in which the controller of the memory device is within the connector of the memory device. By including the controller within the connector rather than within a common housing with memory modules, the form factor of the memory device may be reduced. Accordingly, the space conventionally used to house the controller can be dedicated to additional memory modules. The memory device may be small and portable, such as a flash memory drive. Alternatively, the memory device may be a part of a larger system that is not easily portable.

The connector, which includes the controller, may be utilized with other devices that may benefit from the controller being within the connector. Such devices may include memory card readers, digital cameras, digital camcorders, portable music players, and other such devices. In addition, the memory device includes a memory module that may be removable from the memory device. The memory module may be removed from a circuit board of the memory device or the connector such that a user may install a different memory module to upgrade or fix the memory device. Alternatively, the removable memory module may allow for easier assembly during manufacturing of the memory device relative to memory modules that require soldering or other fixation mechanisms. The memory module may be installed in other devices that utilize memory, such as a motherboard, digital device, or other device that includes a memory.

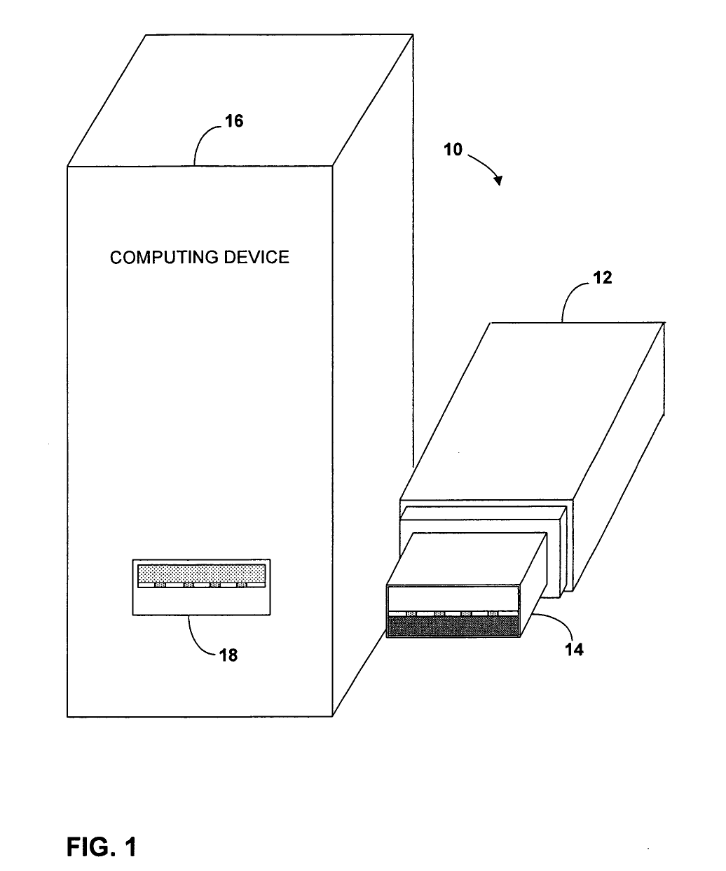

FIG. 1 is a perspective view of an exemplary flash memory device 10 and computing device 16. As shown in FIG. 1, computing device 16 includes port 18. Memory device 10 includes device housing 12 and connector 14. Connector 14 may be inserted into port 18 such that computing device 16 and memory device 10 are electrically coupled. In the example of FIG. 1, connector 14 is a universal serial bus (USB) connector that couples to port 18, which is a USB port. Computing device 16 may be referred to as a host device, in which case, port 18 may be referred to as a host port.

Computing device 16 may be a personal computer, notebook computer, server, personal digital assistant (PDA), portable music player, or any other device that may store or transfer data. Port 18 may be located within the housing of computing device 16 or attached to the computing device through a cable or other structure. Port 18 may be connected to a motherboard or other circuitry of computing device 16 such that a processor within computing device access data when computing device 16 is inserted into port 18.

Memory device 10 receives data from computing device 16 through the connection made between connector 14 and port 18. Device housing 12 houses and protects the components of device 10, such as a flash memory module (FMM) (not shown) and a printed circuit board (PCB) (not shown). Memory device 10 itself may be referred to as a host device with respect to the FMM, in some embodiments. Device housing 12 may be removed from memory device 10 to expose an internal FMM. In other embodiments, connector 14 may be removable from memory device 10. Unlike conventional housings, however, device housing 12 does not house the controller. Instead, the controller is located outside of device housing 12, i.e., within connector 14.

Memory device 10 may be designed to be very small and portable. The size of memory device 10 may be small enough for a user to attach a keychain to place in a pocket of the user. Since connector 14 may be a standard USB connector, if the controller is placed within connector 14, the space needed to house other components (such as FMMs) can be reduced relative to a device that houses the controller with the FMM. Alternatively, the same housing conventionally used to house both the controller and the FMMs could be used to house additional FMMs if the controller were removed from such housing and integrated into connector 14.

Connector 14 may be approximately 12 millimeters (mm) in width, 12 mm in length, and 4.5 mm in height. Generally, device housing 12 may be any size, but the device housing may be the same size or smaller than connector 14. Usually, the length of device housing 12 is greater than 12 mm, but the device housing may possibly be shorter than the length of connector 14. Memory device 10 may be larger in size when including higher capacity FMMs or multiple FMMs.

Preferably, memory device 10 includes flash memory, MRAM, or electrically erasable programmable read only memory (EEPROM), which stores the data. Flash memory is a form of nonvolatile memory, wherein the nonvolatile memory does not require power to retain the stored data. Flash memory is re-writable, supports fast data transfer rates, and needs no power source to retain the data stored in the memory. Flash memory includes forms such as Smart Media, Secure Digital, CompactFlash, Memory Stick, xD, and other types of media. An FMM, as described herein, also utilizes flash memory. In some embodiments, memory device 10 may include non-flash memory modules to store the data. Such memory may include static random access memory (SRAM), dynamic random access memory (DRAM), synchronous dynamic access memory (SDRAM), or any other type of memory type. Flash memory will be described herein as an exemplary memory type.

Connector 14 of memory device 10 is described herein as a USB connector which conforms to standard USB dimensions and protocols. Connector 14 is shown as a USB “A” type connector; however, the connector may be constructed as a USB “B” type connector in other embodiments. Connector 14 may support USB 1.1 or USB 2.0 protocols, where USB 2.0 supports faster data transfer rates. In some embodiments, connector 14 may be configured to conform to an IEEE 1394 connector, PCI connector, serial ATA connector, IDE connector, PCMCIA connector, SATA connector or any other connector which may transfer data to or from computing device 16. In any case, a controller resides within connector 14.

Memory device 10 may be hot-swappable (or hot-pluggable) with port 18 and computing device 16. Hot-swapping is the ability to add or remove components of a machine while the machine continues to operate. Therefore, memory device 10 may be added to or removed from computing device 16 without causing damage to the memory device or computing device. Both computing device 16 and memory device 10 may include a protection circuit and firmware supporting hot-swappability, which can protect the memory from a power surge that could occur when memory device 10 is added or removed from computing device 16. The hot-swapping firmware protocols may allow memory device 10 to be detected once coupled to and removed from computing device 16 while also supporting some type of automatic recovery process. Hot-swapping may also be supported though other connection types, such as IEEE 1394, PCMCIA, and SATA interface protocols. In some cases, memory device 10 may support hot-swapping of an FMM within the memory device.

Connector 14 may be constructed of a metal alloy shield which surrounds a housing (not shown) formed of a plastic material. In this case, the housing within the metal alloy shield may hold the controller, i.e., within the connector. The housing that holds the controller may be fitted with a plurality of metallic contacts which couple to metallic contacts of port 18. The metallic contacts may be plated in silver, gold, or another conductive material. Connector 14 may also be constructed without a metal alloy shield. In this case, the connector 14 is shieldless and the housing that holds the controller is the connector itself. Device housing 12 may be constructed of a metal alloy or molded plastic. Device housing 12 may be formed into any shape or size which can surround the internal components of memory device 10. Such shapes of device housing 12 may include a cube, rectangular cube, cylinder, or any other possible shape. Device housing 12 may also be ergonomically shaped to facilitate handling by human fingers, and the housing may additionally include a rubber or soft coating to promote a tactile contact area between the housing and skin of the user. In some embodiments, connector 14 and device housing 12 may be separated from each other. In this manner, device housing 12 may be easily attached to connector 14 during manufacturing or a user may upgrade memory device 10 by replacing the old device housing with a new device housing that includes more data storage capacity or supports faster data transfer rates.

In some embodiments, connector 14, which includes the controller of memory device 10, may be utilized in devices other than data storage devices. For example, the controller of connector 14 may support data transfer between computing device 16 and another computing device, data transfer to a printing devices, or data transfer any other type of device. For example, a controller contained within a digital watch (or any small portable device) may be alternatively included within a connector that couples the watch to a computer. Therefore, the watch may be reduced in thickness relative to a watch that includes the controller. In other examples, connector 14 may be located directly on a computing device or located at the end of a data transfer cable.

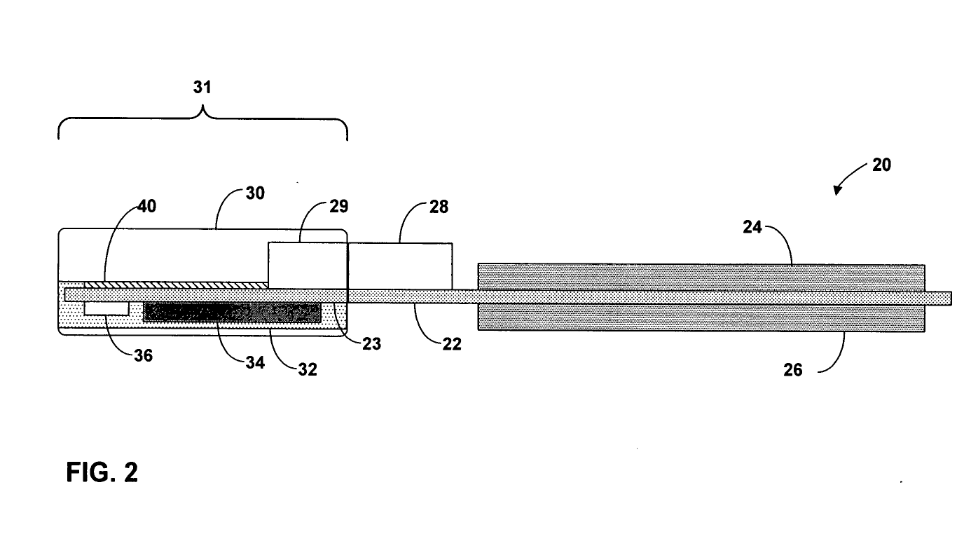

FIG. 2 is a cross sectional view illustrating a controller located within a connector of an exemplary flash memory device. Memory device 20 of FIG. 2 is one exemplary embodiment of memory device 10 of FIG. 1. As shown in FIG. 2, memory device 20 includes printed circuit board (PCB) 22 coupled to FMM 24 and 26. Mating connector 28 is coupled to mating connector 29, such that memory device 20 is created. Connector shield 30 surrounds connector housing 32 that encloses PCB 23, controller 34, and clock 36. Contacts 40 are located on the surface of connector housing 32. A device housing, similar to device housing 12 of FIG. 1, is not shown, but would typically be included to protect FMMs 24 and 26.

Controller 34 resides completely within connector shield 30 which outlines the connector. In the example of FIG. 2, controller 34 also resides within connector housing 32 although the invention is not necessarily limited in this respect. The connector of device 20 may be referred to as an intelligent connector insofar as it includes a controller. Controller 34 does not require any additional space outside of connector shield 30. In this manner, PCB 22 does not need space to hold controller 34. Therefore, PCB 22 may be constructed smaller relative to a PCB that couples to a controller. Alternatively, PCB 22 or may include more memory capacity given the same form factor as a PCB that couples to a controller. In some embodiments, a portion of controller 34 may reside outside of connector shield 30. For example, controller 34 may be attached to PCB 23 that extends beyond connector shield 30 or connector housing 32.

Mating connectors 28 and 29 securely connect the two portions of memory device 20. In this manner, connector 31 of memory device 20 may be attached to or removed from the rest of the device. By manufacturing connector 31 separately from the remainder of memory device 20, the construction process of the memory device can be simplified relative to constructing the entire memory device as one structure. For example, one connector 31 may be used in memory device 20 that includes a number of different storage capacities. FMMs 24 and 26 are coupled to PCB 22 through a plurality of contacts, but neither FMM is attached directly to controller 34. Both FMMs 24 and 26 may be removable from PCB 22 such that a user may replace one or both of the FMMs during FMM failure or upgrade. While FMMs 24 and 26 are located on opposite surfaces of PCB 22, the FMMs may be located on the same side of the PCB. In some embodiments, more than two FMMs may be coupled to PCB 22.

Mating connector 29 is attached to PCB 23 and shield 30. PCB 23 is also electrically coupled to controller 34, clock 36, and contacts 40. Connector housing 32 is formed to surround or enclose controller 34, and clock 36. Connector housing 34 may partially surround PCB 23 in some embodiments. Contacts 40 are attached to PCB 23 through soldering or other metal bonding technique. While contacts 40 include four electrical contacts, only one contact is shown in FIG. 2. Three other contacts 40 are located behind the one contact of FIG. 2. In some embodiments, a greater or fewer number of electrical contacts may be attached to PCB 23. In some embodiments, controller 34 is embedded within connector housing 32 within connector shield 30, but in other cases an additional connector housing 32 may not be needed within connector shield 30. Another embodiment is the connector housing does not have a connector shield 30 and thus form a shieldless connector.

Controller 34 and clock 36 are each attached to PCB 23 through a plurality of electrical contacts or pins. PCB 23 provides the circuits that allow signals to be sent between the components of memory device 20. In some embodiments, contacts 40, clock 36, or controller 34 may be formed within PCB 23.

Connector housing 32 may be constructed of a non-conductive and moldable polymer, such as polyurethane or polypropylene. In some embodiments, connector housing 32 may be manufactured of a material which conducts heat from the operative components to facilitate heat dissipation, where the heat is generated from the electrical current within memory device 20. Connector housing 32 may be formed around the adjacent components or pre-formed and fitted to the components attached to PCB 23.

Locations of controller 34 and clock 36 may be varied with respect to PCB 23. For example, controller 34 may be located behind clock 36. In other embodiments, clock 36 may be placed within mating connector 29 or attached to PCB 22 behind connector housing 32. In other embodiments, controller 34 may include circuitry on two or more separate components attached to PCB 23.

PCB 23 is shown as a substantially flat component, but in other cases, the PCB may be constructed to include curves or angles which create a non-flat shape of the PCB. Different shapes of PCB 23 may create more space to add other FMMs or allow memory device 20 to be designed in a variety of shapes and sizes. In other embodiments, PCB 22 may be flexible to support memory device 20 design which may be useful to increase device durability or provide increased design flexibility of the memory device housing.

In some embodiments, controller 34 may be housed within connector housing 32 while PCB 22 and PCB 23 are one continuous component. While the connector may not be separable from the remainder of memory device 20, FMM 24 and FMM 26 are still removable. By eliminating mating connectors 28 and 29, memory device 20 complexities and cost may be reduced, while further decreasing the size of the memory device or increasing the space available to store data relative to a memory device that includes mating connectors 28 and 29.

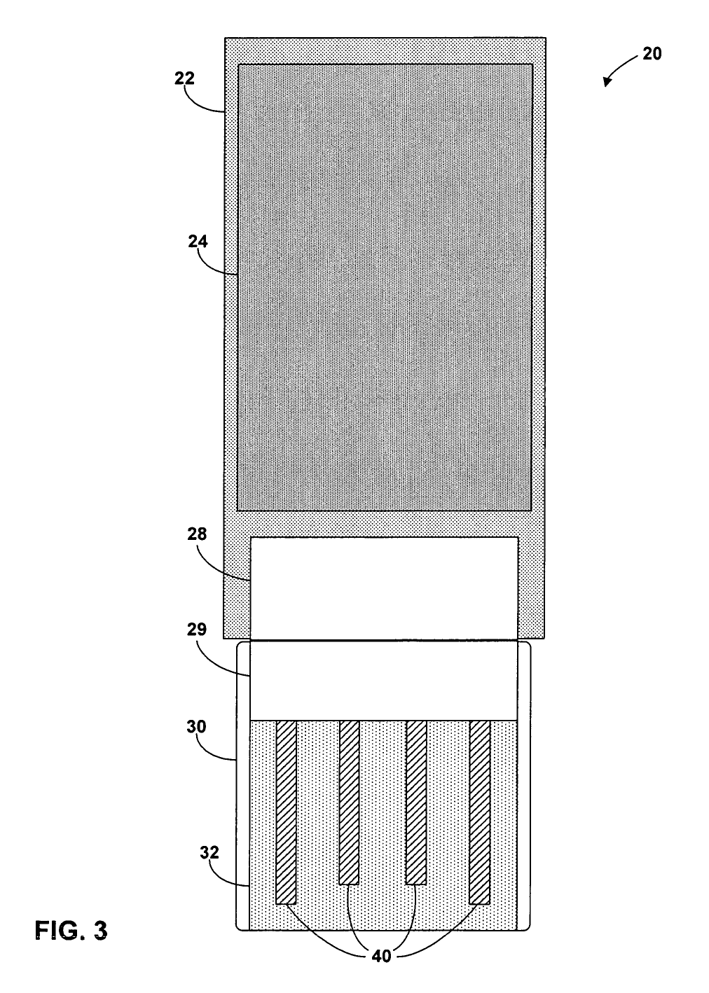

FIG. 3 is a top view of an exemplary flash memory device. As shown in FIG. 3, memory device 20 includes PCB 22, FMM 24, mating connectors 28 and 29, connector shield 30, connector housing 32 and contacts 40. The top portion of connector shield 30 has been removed to show connector housing 32 and contacts 40 within the shield. Mating connectors 28 and 29 connect the connector portion of memory device 20 to the memory portion of the device. Some components of memory device 20, such as controller 34 and FMM 26 are not shown.

PCB 22 and FMM 24 may be rectangular in shape, but could assume other shapes. PCB 22 may also support multiple FMMs on one side of the PCB. In this manner, the storage capacity of memory device 20 may be increased or decreased in smaller storage amounts.

Memory device 20 is configured with a connector designed to match a standard USB A connector. In some embodiments, memory device 20 may include a connector configured to match another standard connector, such as connectors for IEEE 1394 or SATA connections. In any case, the connector includes the controller, i.e., controller 34 of FIG. 2. The controller may be designed to fit within the connector to be included in memory device 20.

In other embodiments, memory device 20 may include multiple connectors that each includes a controller for the specific protocol associated with the connector. For example, memory device 20 may include both an IEEE 1394 connector and a USB A connector so that a user is not restricted to one type of connection. Alternatively, mating connector 28 may be removed from mating connector 29 and attached to a different mating connector of another type of connector. In this manner, a user may only need to store data on one memory device 20 and swap connectors to retrieve the data from the memory device through any number of connections.

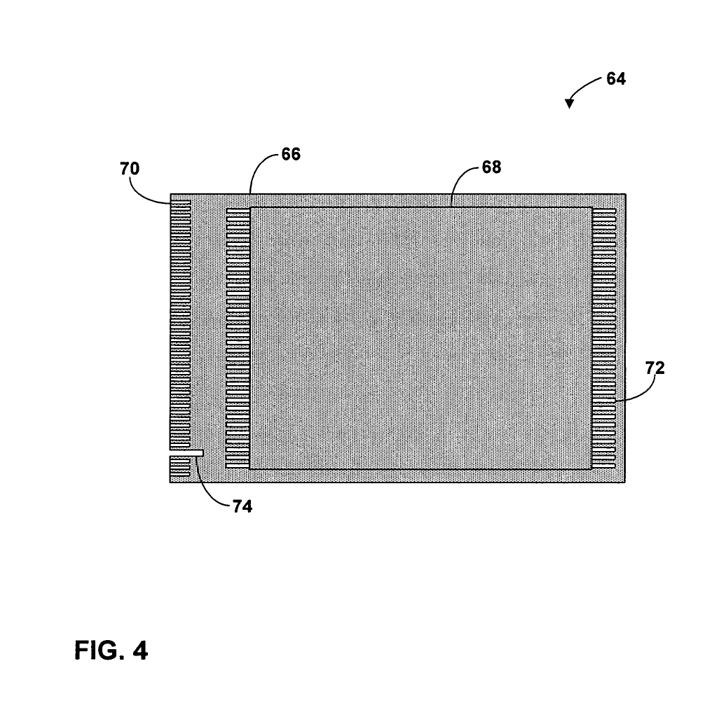

FIG. 4 is a top view of an exemplary flash memory module (FMM). As shown in FIG. 4, FMM 64 may be similar to FMM 24 or FMM 26 of FIG. 2. FMM 64 includes circuit board 66, memory circuit 68, memory pins 72, connector pins 70, and keyed slot 74. FMM 64 may be electrically coupled to a printed circuit board or other circuitry to transfer data to or from the FMM by snapping or inserting the FMM into place. FMM 64 may be configured to store data in varying capacities and transfer data with fast transfer rates. In some cases, FMM 64 does not need a power source to retain stored data, but in other cases, the FMM may require a small power source for data storage. The device coupled to FMM 64 includes a controller configured to support the FMM.

Memory circuit 68 may be a thin small outlined package (TSOP). The TSOP is a type of DRAM package that utilizes gull-wing shaped memory pins 72 to electrically connect memory circuit 68 to circuit board 66. Memory circuit 68 mounts directly to a circuit board 66 surface. Circuit board 66 is a printed circuit board. In some embodiments, multiple memory circuits 68 may be stacked on top of each other to increase the data storage capacity. While memory circuit 68 may be of many different sizes and dimensions, an exemplary memory circuit may be 20 millimeters (mm) in length, 12 mm in width, and 1 mm in height.

In other embodiments, memory circuit 68 may be a type of DRAM package different from the TSOP. For example, a dual in-line package (DIP), a small outline J-lead (SOJ), or a very, very thin small outline package (sometimes called “WSOP”) memory circuit may be used to store data. In addition, memory circuit 68 may be a chip scale package (CSP) which connects to circuit board 66 with a ball grid array (BGA) instead of memory pins 72. The CSP form of memory circuit 68 may be capable of the highest data storage density. In some embodiments, memory circuit 68 includes 48 memory pins.

Memory circuit 68 includes a protection circuit, and may also include firmware, supporting hot-swappability, which can protect the memory circuit from a power surge that could occur when FMM 64 is added or removed from a host device that is currently operating. The protection circuit may allow FMM 64 to be detected once coupled to and removed from memory device 10 while also supporting some type of automatic recovery process. In other embodiments, the protection circuit may be used when FMM 64 is coupled to computing device 16.

Memory pins 72 are attached to conductive elements on circuit board 66. Memory pins 72 may be soldered onto circuit board 66 to create a secure connection between the pins and the circuit board. Circuit board 66 is connected to another circuit board, similar to PCB 22 of FIG. 2, using connector pins 70 along the edge of circuit board 66. For example, the edge of circuit board 66 includes 44 connector pins 70. Connector pins 70 include two sets of 16-bit data input/output lines and other control signal, voltage, and ground connections. In some embodiments, connector pins 70 may be located along more than one edge of circuit board 66 or on a flat surface of the circuit board. Circuit board 66 also includes keyed slot 74 to correctly orient FMM 64 during the FMM insertion by mating to a protrusion of the circuit board of a memory device. In other embodiments, the edge of circuit board 66 may contain more than one keyed slot for orientation. Alternatively, keyed slot 74 may be an angled corner of circuit board 74.

Circuit board 66 may be capable of accepting multiple memory circuits 68. For example, other memory circuits may be placed side by side or stacked on top of each other. Multiple memory circuits may increase the storage capacity of FMM 64 and also increase the size of the FMM relative to single memory circuit FMM 64. Each memory circuit 68 may store different amounts of data. Generally, the storage capacity of memory circuit 68 is between 8 megabytes (MB) and 1024 MB. However, smaller or larger storage capacities are possible as the capacity of memory circuits continues to increase due to technological advances in the electronics industry. In the example of FIG. 2, FMM 24 and 26 may each store 1 GB of data (approximately 1024 MB) to allow memory device 20 to store 2 GB of data.

In addition to FMM 64 being used in memory devices such as memory device 20, the FMM may be used as memory in other computing or storage devices. For example, FMM 64 may be coupled to computer motherboards, digital cameras, personal digital assistants (PDAs), hard drives, cell phones, video game consoles, or any other device that uses a solid-state memory. One advantage to FMM 64 is that any device that includes a controller with an interface for a TSOP (or the packaging used in the FMM) may interrogate the FMM without an additional interface. By removing the need for an additional interface, manufacturing costs can be reduced, and FMM 64 can have more compatibility relative to memory that requires a specific interface. In addition, FMM 64 may be easily replaceable or upgradeable by the user. The user may increase the storage of the device by installing a new FMM or replace a damaged FMM. In manufacturing, FMM 64 may be easily snapped in place during device assembly or easily replaced if the FMM is inoperable relative to re-soldering a new memory circuit into the device. In the case of memory device 20, a user may increase the data storage or replace a failed FMM with a new FMM at a reduced cost as compared with purchasing a new memory device.

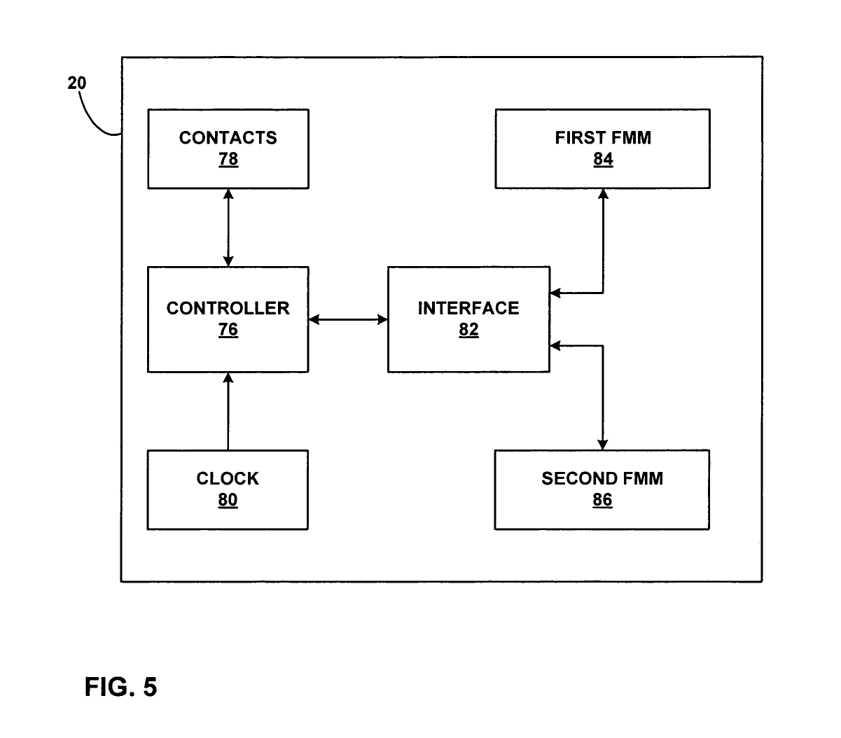

FIG. 5 is a block diagram of components of an exemplary flash memory device. As shown in FIG. 5, memory device 20 includes controller 76, contacts 78, clock 80, interface 82, FMM A 84 and FMM B 86. Contacts 78, controller 76, clock 80, first FMM 84, and second FMM 86 are similar to contacts 40, controller 34, clock 36, FMM 24, and FMM 26 of FIG. 2, respectively. Contacts 78 couple memory device 20 to a computing device, such as computing device 16 of FIG. 1. In the example of FIG. 5, contacts 78 are a 4 pin USB A connection. Power is delivered to memory device 20 though contacts 78.

Controller 76 includes circuitry to operate memory device 20 and communicate with the computing device. Controller 76 circuitry may include a microprocessor, program ROM, program RAM, data RAM, a buffer, multiplexer (MUX) and any other components required to transfer data to and from first FMM 84 or second FMM 86. Controller 76 includes firmware instructions installed during manufacture; however, a computing device may update the firmware. In some embodiments, controller 76 includes 48 pins to connect the controller to a printed circuit board, similar to PCB 23 of FIG. 2.

Controller 76 utilizes clock 80 to maintain data transfer rates and coordinate signal timing. Generally, clock 80 may have a frequency between 5 megahertz (MHz) and 20 MHz. However, a slower or faster frequency may be used. Clock 80 may be constructed of a ceramic or crystal oscillator.

Interface 82 may be located on or within a printed circuit board and provide the physical connection between controller 76 and first FMM 84 and second FMM 86. Controller 76 uses a MUX, or multiplexing circuit, to send complex data input/output signals and control signals to interface 82 to reduce the number of connections required within memory device 20. Interface 82 separates the signals and sends them to first and second FMMs 84 and 86. Controller 76 may allow data to be transferred between first FMM 84 and second FMM 86 to manage large pieces of data or at the request of a user. In some embodiments, controller 76 may send separate signals for each of first and second FMMs 84 and 86. In other embodiments, interface 82 and controller 76 may support more than two FMMs within memory device 20. First FMM 84 and second FMM 86 are similar to FMM 64 described in FIG. 4. Any combination of FMM 84 and FMM 86 may be recognized by interface 82, and other FMMs may be used to replace either FMM 84 or FMM 86.

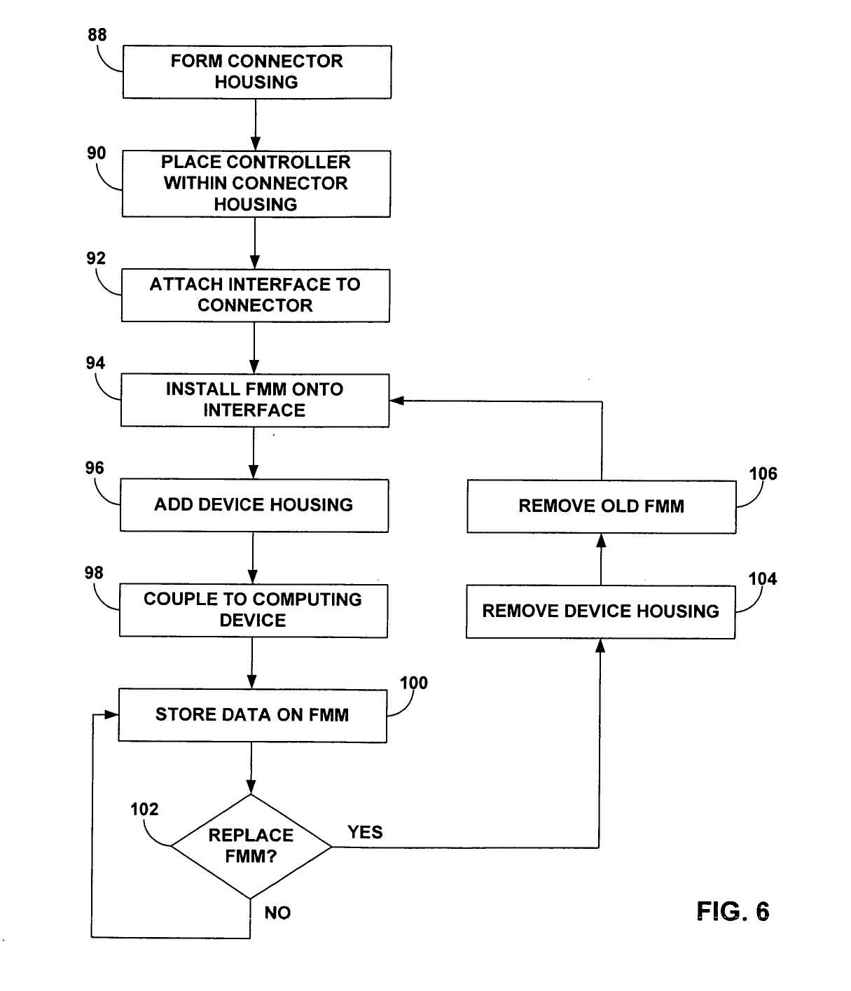

FIG. 6 is a flow diagram illustrating an exemplary life cycle of memory device 20 of FIG. 2 with a removable flash memory module. A machine begins memory device 20 construction by first forming connector housing 32 (88) and then placing controller 34 of FIG. 2 and other components within the connector housing (90). An interface, such as PCB 23, is attached to the connector (92) before FMM 24 or FMM 26 is installed onto the interface (94). Once each FMM 24 and 26 are installed, the machine adds device housing 12 to complete construction of memory device 20 (98). In some embodiments, connector housing 32 may be formed around controller 34 and other components. Alternatively, the components of connector 31 may not be contained within a housing.

The finished memory device 20 is distributed to a user, where the user couples memory device 20 to computing device 16 (98). The user may store data onto FMM 24 and FMM 26 of memory device 20 until the storage capacity is met (100). If the user does not desire to replace FMM 24 or FMM 26 (102), the user continues to store data onto memory device (100). If the user wants to replace FMM 24 or FMM 26 (102), the user removes device housing 12 (104), removes one or both of the FMMs (106), and installs a new FMM onto the interface (94).

In some embodiments, the user may send memory device 20 back to the manufacturer or retail store to upgrade the memory of the device. In other embodiments, memory device 20 or computing device 16 may recognize that FMM 24 or FMM 26 is beginning to fail. In this case, the user may backup the data on memory device 20 to another data storage device and replace the malfunctioning FMM.

Alternatively, the user may keep connector 31 and purchase a new device housing 12 that includes a new FMM. Removing connector 31 from device housing 12 may be less complicated for the user relative to removing FMM 24 or FMM 26. Further, by eliminating the need for a user to handle components within device housing 12, the integrity of device components can be preserved as compared to the user removing an FMM.

Various modifications can be made to the techniques described herein without departing from the spirit and scope of the invention. For example, although the controller is shown to be located within a USB connector, other connectors may include a controller. These and other embodiments are within the scope of the following claims.

1. A device for storing data, the device comprising:
a device housing;
a memory module within the device housing that stores data; and
a connector that extends from the device housing comprising:
a plurality of electrical contacts that facilitate a connection to a host port; and
a controller circuit that manages data transfer and data storage to the memory module, wherein the controller resides outside of the device housing.

2. The device of claim 1, wherein the controller circuit resides completely within the connector.

3. The device of claim 2, wherein the controller circuit is embedded within a connector housing.

4. The device of claim 1, wherein the host port is electrically coupled to a computing device, and wherein the controller circuit supports inserting the connector into and removing the connector from the host port while a computing device connected to the host port is operating.

5. The device of claim 1, wherein the connector is a standard universal serial bus (USB) connector.

6. The device of claim 1, wherein the connector and the device housing each house a printed circuit board.

7. The device of claim 1, wherein one printed circuit board resides within both the connector and the device housing.

8. The device of claim 1, wherein the memory module is removable from the device housing.

9. The device of claim 1, wherein the memory module is a nonvolatile memory module.

10. The device of claim 1, wherein two or more memory modules reside within the device housing.

11. A removable connector for a first device, the device comprising:
a plurality of electrical contacts that facilitate a connection of the first device to a port of a second device; and
a controller circuit that manages data transfer between the second device and the first device when the first device and the second device are connected via the removable connector, wherein the removable connector is removable from the first device.

12. The removable connector of claim 11, wherein the controller circuit resides completely within a connector housing.

13. The removable connector of claim 12, wherein the controller circuit is embedded within the connector housing.

14. The removable connector of claim 11, wherein the controller circuit includes protection circuitry to protect the removable connector from a power surge upon insertion of the removable connector into the second device while the second device is operating.

15. The removable connector of claim 11, wherein the connector is a standard universal serial bus (USB) connector.

16. The removable connector of claim 11, further comprising a removable memory module, wherein the controller circuit is electrically coupled to the memory module with a module connector.

17. A memory module for storing data, the memory module comprising:
a circuit board;
a plurality of electrical contacts that facilitate a connection to a host device; and
a memory circuit coupled to the circuit board, wherein the memory circuit includes protection circuitry to protect the memory circuit from a power surge upon insertion of the memory module into the host device while the host device is operating.

18. The memory module of claim 17, wherein the memory circuit is a flash memory circuit of a thin small outlined package (TSOP).

19. The memory module of claim 18, further comprising a keyed slot on an edge of the circuit board, wherein the electrical contacts are located along the edge.

20. The memory module of claim 17, wherein the memory circuit stores data within a universal serial bus (USB) memory device.
